(19) United States
(12) Patent Application Publication
(10) Pub. No.: US 2010/0034230 A1
(43) Pub. Date: Feb. 11, 2010

(54) ARSENIC DOPED SEMICONDUCTOR LIGHT EMITTING DEVICE AND ITS MANUFACTURE

(75) Inventors: Wataru TAMURA, Kawasaki-shi (JP); Tatsuma Saito, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 12/535,985

(22) Filed: Aug. 5, 2009

(30) Foreign Application Priority Data
Aug. 11, 2008 (JP) 2008-207217

(51) Int. Cl. H01S 5/026; H01L 21/00

(52) U.S. Cl. 372/45.011; 438/45; 257/E21.002

(57) ABSTRACT

A semiconductor light emitting device includes: a substrate; a first clad layer formed above the substrate and made of AlGaInP mixed crystal of a first conductivity type; an active layer formed on the first clad layer and made of AlGaInP mixed crystal; and a second clad layer formed on the active layer and made of AlGaInP mixed crystal of a second conductivity type opposite to the first conductivity type, wherein the first clad layer and the second clad layer each have a band gap wider than a band gap of the active layer, and at least one of the active layer and the first and second clad layers is doped with arsenic at an impurity concentration level not changing the band gap. Carbon capturing is suppressed, and surface morphology is suppressed from being degraded.

### CROSS-REFERENCE TO RELATED APPLICATIONS

This application is based upon and claims the benefit of priority of the prior Japanese Patent Application No. 2008-207217 filed on Aug. 11, 2008, the entire contents of which are incorporated herein by reference.

### BACKGROUND

1. Field

The present invention relates to a semiconductor light emitting device and its manufacture method, and more particularly to a semiconductor light emitting device having a lamination structure of AlGaInP mixed crystals and its manufacture method.

2. Related Art

Group III-V compound semiconductor containing P as group V element tends to have a band gap broader than that of compound semiconductor containing As as group V element. It can be said that this tendency is suitable for emission of visible light A light emitting diode (LED) having an active layer made of AlGaInP mixed crystal is widely used as an LED in the wavelength range from yellow to red An LED structure of a double hetero structure is formed by epitaxially growing, for example, on an n-type GaAs or AlGaAs substrate, if necessary through an n-type buffer layer formed on the substrate, an n-type AlGaInP clad layer having a wide band gap, an AlGaInP active layer having a narrow band gap, a p-type AlGaInP clad layer having a wide bang gap, and a p-type current diffusion layer, by metal organic chemical vapor deposition (MOCVD).

JP-A-HEI-11-121796 (Stanley Electronic Co., Ltd.), which is incorporated herein by reference, indicates the problem that p-type impurities diffuse from a p-type AlGaInP clad layer and a p-type current diffusion layer into an AlGaInP active layer and that a pn junction moves into an n-type AlGaInP clad layer, and proposes in the description of the embodiments the structure that the p-type AlGaInP clad layer has a lamination structure and that a portion of the p-type clad layer in contact with the active layer is made of a non-doped or a lightly doped region.

JP-A-HEI-6-302852 indicates the problem of unstable quality of a light emitting diode because an emission efficiency depends on impurities not intentionally doped during crystal growth by metal organic chemical vapor deposition (MOCVD) rather than a carrier concentration in an active layer, reports a variation in emission efficiency which occurs each time organic metal gas as group III source gas is exchanged, and points out Si and O as the impurities

JP-A-2008-108964 (Stanley Electronic Co., Ltd.), which is incorporated herein by reference, indicates that secondary ion mass spectroscopy (SIMS) of AlGaInP light emitting devices teaches carbon (C) as impurities which lower an emission efficiency, and proposes to adjust an average carbon concentration to 7×10¹⁶ atoms/cm³ or smaller by adjusting V/III ratio to 60 or larger during organic metal vapor growth of three layers of an AlGaInP active layer and AlGaInP clad layers on both sides of the active layer.

### SUMMARY OF THE INVENTION

It is an object of the present invention to provide a compound semiconductor device and its manufacture method capable of suppressing carbon from being captured and surface morphology from being degraded.

It is another object of the present invention to provide a semiconductor light emitting device and its manufacture method capable of improving an emission efficiency.

According to an aspect of the present invention, there is provided a semiconductor light emitting device including:

a substrate;

a first clad layer formed above the substrate and made of AlGaInP mixed crystal of a first conductivity type;

an active layer formed on the first clad layer and made of AlGaInP mixed crystal; and

a second clad layer formed on the active layer and made of AlGaInP mixed crystal of a second conductivity type opposite to the first conductivity type,

wherein the first clad layer and the second clad layer have a band gap wider than a band gap of the active layer, and at least one of the active layer and the first and second clad layers is doped with arsenic at an impurity concentration level not changing the band gap.

According to another aspect of the present invention, there is provided a method for manufacturing a semiconductor light emitting device including steps of:

transporting a semiconductor substrate into an organic metal vapor growth system; and

epitaxially growing a first clad layer of AlGaInP mixed crystal of a first conductivity type, an active layer of AlGaInP mixed crystal, and a second clad layer of AlGaInP mixed crystal of a second conductivity type opposite to the first conductivity type, sequentially by organic metal vapor growth above the semiconductor substrate, while doping in situ, at least one of three layers of the first and second clad layers and the active layer, with arsenic at an impurity concentration level not changing a band gap.

By doping a proper amount of arsenic to the extent that a band gap or a substantial composition will not be changed in the epitaxial growth of an AlGaInP epitaxial layer, it becomes possible to suppress carbon from being captured and surface morphology from being degraded.

### BRIEF DESCRIPTION OF THE DRAWINGS

FIG. 1 is a cross sectional view illustrating the structure of manufactured samples.

FIG. 2 is a block diagram illustrating the structure of an MOCVD system used.

FIG. 3 is a graph illustrating relation between V/III ratio during epitaxial growth and carbon concentration in grown (Al_{0.7}Ga_{0.3})_{0.5}In_{0.5}P:As epitaxial layer.

FIG. 4 is a graph illustrating change in carbon concentration relative to arsenic concentration in case of low V/III ratio (20 to 40) at which carbon concentration becomes high.

FIG. 5 is a graph illustrating change in surface roughness Rms relative to V/III ratio.

FIG. 6 is a graph illustrating relation between surface roughness Rms and arsenic concentration.

FIG. 7 is a schematic cross sectional view illustrating the structure of other manufactured samples.

FIG. 8 is a graph illustrating the relation between photoluminescence (PL) intensity and arsenic concentration.

FIG. 9 is a graph illustrating the relation between arsenic concentration in (Al_{z}Ga_{1-z})_{0.5}In_{0.5}P layers and V/III ratio, when Al composition is changed.

FIG. 10 is a graph illustrating arsenic concentration distribution in a (Al_{0.25}Ga_{0.75})_{0.5}In_{0.5}P:As layer epitaxially grown on an n-type GaAs substrate.

FIGS. 11A and 11B are a schematic cross sectional view illustrating the structure of a comparative example and a plan view illustrating a plan shape of a p-side electrode.

FIGS. 12A to 12G are partial cross sectional views illustrating the structures of samples doped with As in any one or ones of clad layers and an active layer.

FIG. 13 is a table collectively illustrating features of comparative examples R1 and R2 and samples S1 to S7.

FIGS. 14A to 14E are cross sectional views and a plan view illustrating various modifications.

FIGS. 15A to 15D are cross sectional views illustrating a semiconductor light emitting device according to another modification.

### DESCRIPTION OF THE PREFERRED EMBODIMENTS

According to researches and developments made by the present inventors and colleagues, carbon concentration of about 7×10¹⁶ atoms/cm³ or higher, or roughly about 10¹⁷ atoms/cm³ or higher, clearly lowers luminance of the LED. Carbon capturing is suppressed by increasing V/III ratio during crystal growth using organic metal gas. Experiments made by the present inventors will now be described.

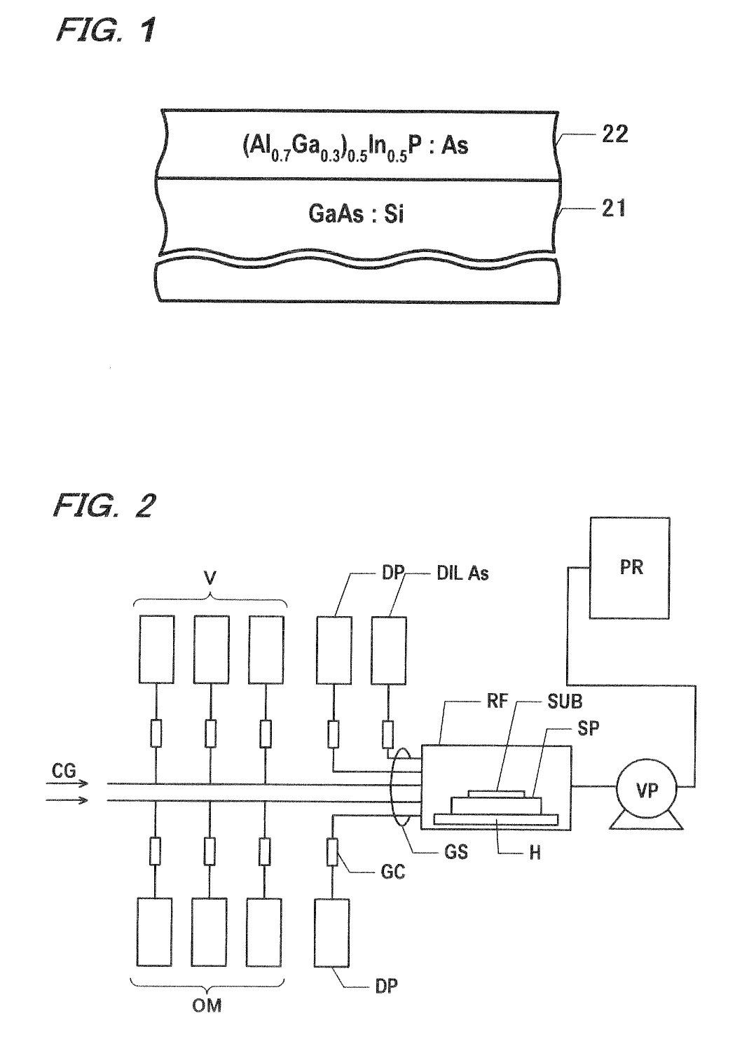

FIG. 1 is a cross sectional view illustrating the structure of crystal growth samples. On an n-type GaAs substrate 21 doped with Si, a (Al_{0.7}Ga_{0.3})_{0.5}In_{0.5}P layer 22 was epitaxially grown to a thickness of about 2 μm by metal organic chemical vapor deposition (MOCVD) at various V/III ratios, while As is doped in situ. Group V element as the composition of growth crystal is P and does not contain As. Samples not doped with As were formed as comparative examples. (Al_{0.7}Ga_{0.3})_{0.5}In_{0.5}P is a composition, for example, adopted as a clad layer.

FIG. 2 is a block diagram illustrating the structure of an MOCVD system used for epitaxial growth. A reaction furnace RF accommodates a susceptor or susceptor SP with a heater H. A substrate SUB for crystal growth is transported or brought into the reaction furnace, and placed on the susceptor SP. A plurality of gas supply systems GS are connected to the reaction furnace RF. Each of the two main gas supply systems GS is connected to gas controllers, each including a mass flow controller and a pressure gauge, and to a carrier gas piping CG. The reaction furnace RF is maintained at a desired pressure by a vacuum (evacuation) pump VP and exhausted via a safety disposal facility PR.

Group V gas sources V, and organic metal gas sources OM which are group III gas sources, are connected the respective carrier gas pipings CG via respective gas controllers CG. Arsine (AsH₃) and phosphine (PH₃) can be supplied as group V source gas. Trimethylaluminum (TMA), trimethylgallium (TMG) and trimethylindium (TMI), which are organic metal gases, can be supplied as group III source gas.

Doping sources DP, i.e. n- and p-type impurities, are supplied independently through each gas controller. Silane (Si H₄) and hydrogen selenide (H₂Se) were used as n-type doping sources. Dimethylzinc (DMZn) was used as p-type doping source. Diluted arsine DILAs diluted to 0.5% with hydrogen was used as arsenic doping source.

Growth temperature was maintained at 760° C., growth pressure was maintained at 10 kPa, and supply amount of group III source gas to the reaction furnace was maintained at 200 μmol/min. Various V/III (mol) ratios were realized by changing supply amount of phosphine as group V source gas. Ratio of supply amount (mol) of arsenic as dopant to supply amount (mol) of group III source material is defined as As/III ratio.

Referring back to FIG. 1, the (Al_{0.7}Ga_{0.3})_{0.5}In_{0.5}P:As layer was grown by changing As/III ratio in a range from 1×10⁻⁴ to 2.5×10⁻¹. V/III ratio was changed in a range from 10 to 120. As compared to the V/III ratio, the As/III ratio is 1/40 at most, and generally is smaller than 1/40. Carbon and arsenic concentrations in the epitaxial layers of the samples were measured by secondary ion mass spectroscopy (SIMS), and surface morphology was evaluated with an inter-atomic force microscope.

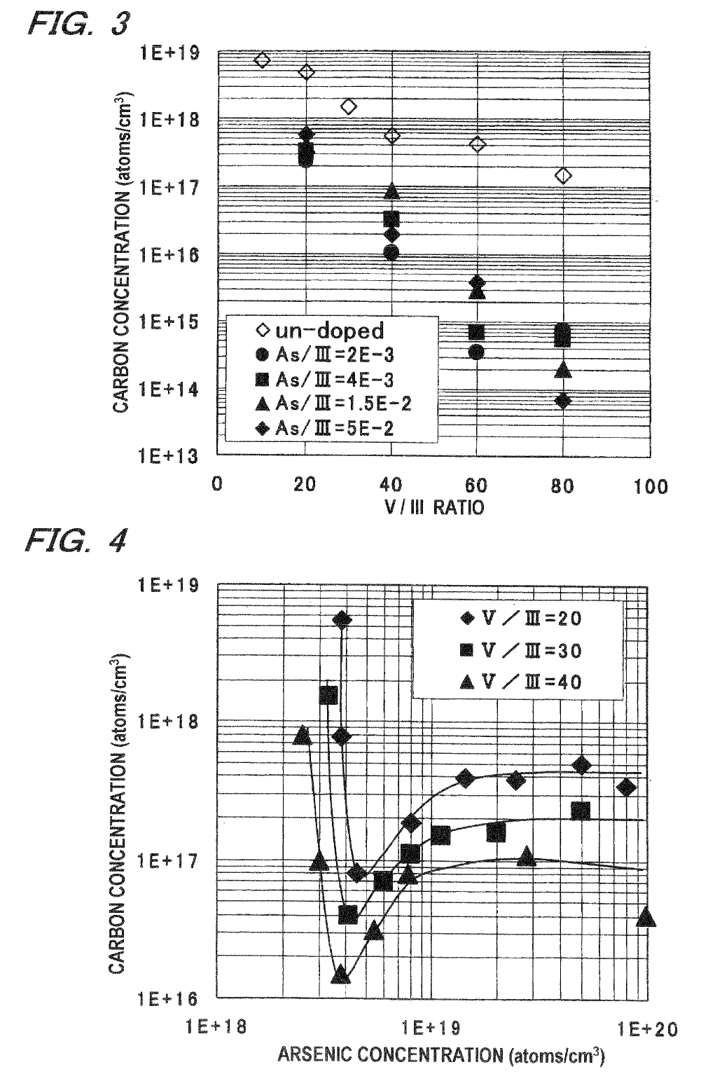

FIG. 3 is a graph illustrating the relation between carbon concentration in the (Al_{0.7}Ga_{0.3})_{0.5}In_{0.5}P:As epitaxial layer and V/III ratio during epitaxial growth, of representative samples. The abscissa represents V/III mol ratio, and the ordinate represents carbon concentration in the unit of atoms/cm³. A parameter, As/III ratio, was changed, among 0 (undoped), 2×10⁻³, 4×10⁻³, 1.5×10⁻², and 5×10⁻². The carbon concentration is an average concentration in the film.

Measured values of samples not doped with As are indicated by outline rhombus ⋄ plots, measured values of samples grown at As/III ratio of 2×10⁻³ (in FIG. 3, 2E−3) are indicated by solid circle • plots, measured values of samples grown at As/III ratio of 4×10⁻³ (in FIG. 3, 4E−3) are indicated by solid square ▪ plots, measured values of samples grown at As/III ratio of 1.5×10⁻² (in FIG. 3, 1.5E−2) are indicated by solid triangle ▴ plots, measured values of samples grown at As/III ratio of 5×10⁻² (in FIG. 3, 5E−2) are indicated by solid rhombus ♦ plots. It is recognized as a whole that as the V/III ratio increases, carbon concentration tends to lower. Plots shown in the figure are values measured for representative samples, and the carbon concentrations of the actually manufactured samples are distributed in broader area.

The arsenic-non-doped (Al_{0.7}Ga_{0.3})_{0.5}In_{0.5}P samples have carbon concentration of about 1×10¹⁹ atoms/cm³(1E19 atoms/cm³), at V/III ratio of 10. Although the carbon concentration reduces as the V/III ratio increases, the carbon concentration is higher than 1×10¹⁷ (1E17) atoms/cm³ even at V/III ratio of 80. In order to set carbon concentration to 7×10¹⁶ (7E16) atoms/cm³ or lower as recommended in JP-A-2008-108964, V/III ratio would preferably be 100 or higher.

The graph shows that as arsenic is doped, carbon concentration in AlGaInP layer lowers considerably. It may be considered that arsenic doping provides a function of suppressing carbon capturing. Tendency that as V/III ratio is increased, residual carbon concentration lowers, is the same as arsenic un-doped cases.

It seems that there is a tendency that at V/III ratio of 80, as As/III ratio is increased, carbon concentration lowers. However, detection limit of SIMS analysis is 5×10¹⁵ atoms/cm³. It is therefore considered that it is meaningless to discuss the magnitude relation of some data at the V/III ratio of 60 and data at the V/III ratio of 80 respectively having carbon concentration of 1×10¹⁵ atoms/cm³ or lower. It seems that as the V/III ratio lowers to 60, 40 and 20, the relation between the As/III ratio and carbon concentration becomes complicated. In order to clarify this, studies were conducted more directly on change in carbon concentration relative to change in arsenic concentration.

FIG. 4 is a graph illustrating change in carbon concentration relative to arsenic concentration in a low V/III ratio (20 to 40) range where the carbon concentration becomes high. The abscissa represents arsenic concentration in the unit of atoms/cm³, and the ordinate represents carbon concentration in the unit of atoms/cm³. It is recognized commonly at each V/III ratio that there is the tendency that as the arsenic concentration increases, the carbon concentration reduces once to take a minimum value, and then increases and saturates.

In a low arsenic concentration range, the carbon concentration becomes high independently of the V/III ratio. It is considered that the effect of suppressing carbon capturing by arsenic is not exhibited sufficiently. As the arsenic concentration increases, the effect of suppressing carbon capturing appears, although there is difference to some extent depending on the V/III ratio As the V/III ratio lowers, the arsenic concentration at which the effect of suppressing carbon capturing become maximum changes slightly higher. The higher the V/III ratio is, the smaller the minimum value of the carbon concentration becomes. It can be considered that the effect of suppressing carbon capturing by the V/III ratio superposes on the effect of suppressing carbon capturing by arsenic.

It is known that as the V/III ratio is increased, there appears effect of suppressing vacancies of group V elements. It can be considered that the lower the V/III ratio is, vacancy concentration of group V element increases more. Considering that arsenic enters the vacancies of group V element, it may be considered that as lower the V/III ratio is, concentration of arsenic atoms entering the vacancies increases more.

As the arsenic concentration is increased further, the carbon concentration increases. Although the carbon concentration is definitely lower than that for arsenic un-doped samples, there is the tendency that as the arsenic concentration increases, the carbon concentration increases and saturates. It can be considered that at least two phenomena, one decreasing and another increasing the carbon concentration with the increase of the arsenic concentration, are contributing.

The residual carbon concentration lowers particularly in the arsenic concentration range at least from 4×10¹⁸ (4E18) atoms/cm³ to 1×10¹⁹ (1E19) atoms/cm³. It is shown that minimum value of the carbon concentration takes 1×10¹⁷ (1E17) atoms/cm³ or lower even at V/III ratio of 20. As the V/III ratio is increased to 30 and 40, the minimum value of the carbon concentration lowers further.

The reason why the carbon concentration increases at high arsenic concentration is not still known. There may be a possibility that not only arsenic atoms enter the vacancies, but also arsenic atoms enter interstitial sites or replace the P sites. It may also be considered that as arsenic is incorporated at a level of 10²⁰ atoms/cm³ or higher, it begins to give mixed crystal phenomenon, to change to AlGaInPAs based material.

In order to suppress carbon capturing during MOCVD growth at a low V/III ratio easy to maintain surface morphology in good state, it is preferable to set the As concentration in a range from 3×10¹⁸ atoms/cm³ to 1×10¹⁹ atoms/cm³ (from 3E18 atoms/cm³ to 1E19 atoms/cm³), or more safely in a range from 4×10¹⁸ atoms/cm³ to 1×10¹⁹ atoms/cm³.

The inventors studied changes in surface morphology relative to change in V/III ratio and arsenic concentration. More specifically, change in surface roughness Rms was measured, Rms being a parameter representative of concave and convex portions of surface morphology.

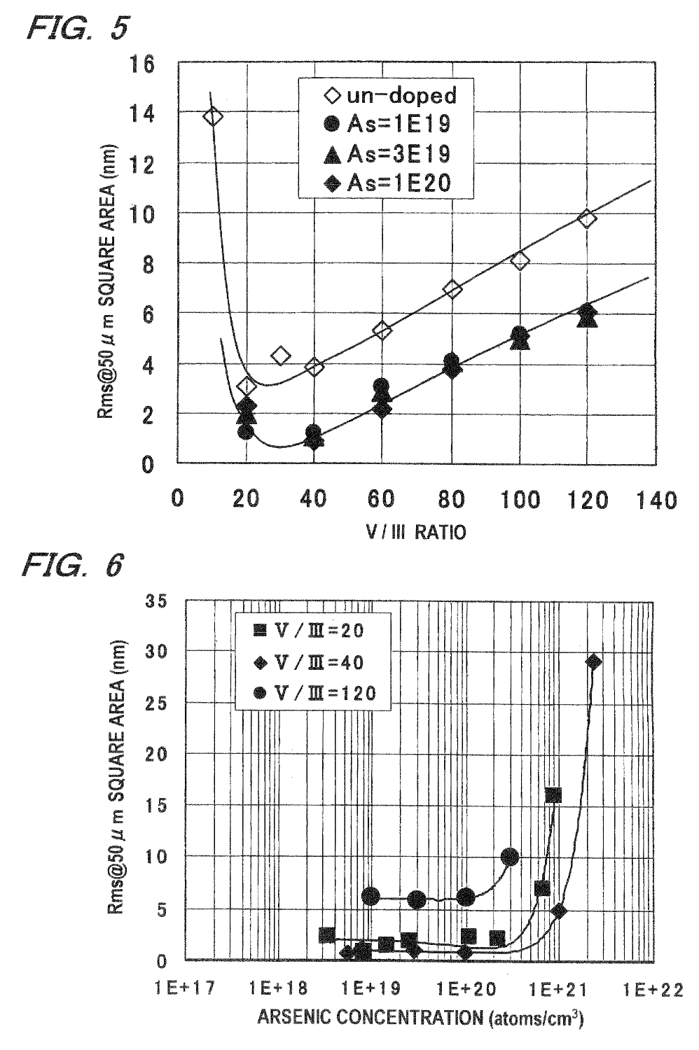

FIG. 5 is a graph illustrating change in surface roughness Rms in 50 μm square area relative to V/III ratio. The abscissa represents V/III ratio, and the ordinate represents Rms in the unit of nm. The graph shows the measurement results with inter-atomic force microscope (AFM) on four cases: arsenic un-doped; and arsenic concentrations of 1×10¹⁹ atoms/cm³, 3×10¹⁹ atoms/cm³, and 1×10²⁰ atoms/cm³ (1E19, 3E19 and 1E20 atoms/cm³) The surface roughness Rms takes a minimum value in V/III ratio range from 15 to 40, and increases on both sides of the minimum value. A tradeoff relation is considered to exist between the tendency that Rms increases as the V/III ratio is increased from the V/III ratio range from about 15 to 40 and the tendency that the carbon concentration lowers as the V/III ratio is increased from 20 shown in FIG. 3.

As compared to As un-doped, the surface roughness reduces definitely when As is doped. In V/III ratio range of from 15 to 60, or more safely in V/III ratio range of 20 to 60, it will be possible to obtain excellent surface morphology while suppressing the carbon concentration by As doping, by growing AlGaInP mixed crystal while doping As in situ. The inventors measured the changes in morphology relative to As doping.

FIG. 6 is a graph illustrating a relation between the surface roughness Rms and arsenic concentration. The abscissa represents an arsenic concentration in the unit of 7×10¹⁶ atoms/cm³, and the ordinate represents Rms in the unit of nm. Change tendencies are shown for three cases of the V/III ratios of 20, 40 and 120. At the V/III ratio of 120, Rms takes approximately a constant value at arsenic concentration equal to or below 1×10²⁰ (1E20) atoms/cm³ or lower, and Rms increases at arsenic concentration higher than 1×10²⁰ (1E20) atoms/cm³. At the V/III ratios of 20 and 40, the surface roughness Rms becomes small and take approximately a constant value in a broader arsenic concentration range.

As the arsenic concentration becomes higher than 1×10²⁰ (1E20) atoms/cm³, more precisely 2×10²⁰ (2E20) atoms/cm³, it seems there is the tendency that the surface roughness Rms increases abruptly. Since the arsenic concentration increases to a composition level, a compositional change occurs and there is a possibility of a new phenomenon to be caused by the compositional change. In order to maintain morphology in a good state, it would be preferable to set the arsenic concentration equal to 2×10²⁰ (2E20) atoms/cm³ or lower. It would be more preferable to set the arsenic concentration equal to 1×10²⁰ (1E20) atoms/cm³ or lower.

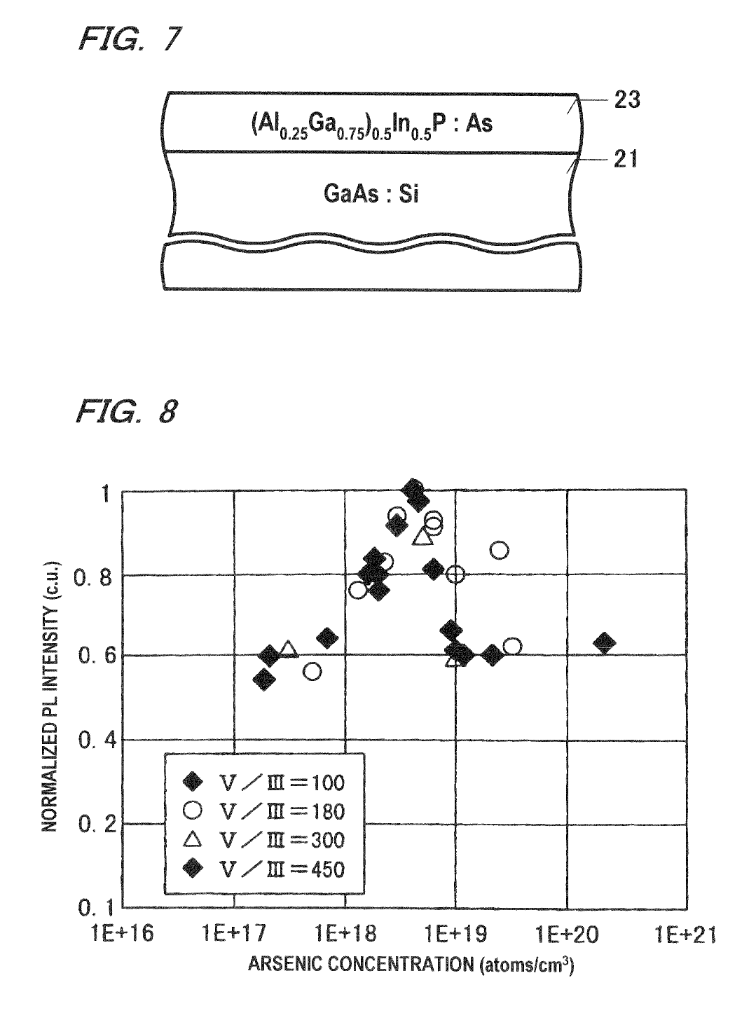

FIG. 7 is a schematic cross sectional view illustrating the structure of other samples having different mixed crystal compositions. An arsenic doped (Al_{0.25}Ga_{0.75})_{0.5}In_{0.5}P:As layer 23 was epitaxially grown by MOCVD to a thickness of about 1 μm, on an Si doped n-type GaAs substrate 21. Composition (Al_{0.25}Ga_{0.75})_{0.5}In_{0.5}P corresponds to a composition of an active (light emitting) layer. As/III ratio was changed in a wide range from 5.0×10⁻⁴ to 5.0×10⁻¹ (5.0E−4 to 5.0E−1), to change the As concentration in a wide range V/III ratio was changed among 100, 180, 300 and 450. Other conditions such as a growth temperature are similar to those of the samples described above. Photoluminescence was measured for these samples.

FIG. 8 is a graph illustrating the relation between a photoluminescence (PL) intensity and an arsenic concentration in the epitaxial layer of these samples. The abscissa represents an arsenic concentration in the unit of atoms/cm³ and in a logarithmic scale, and the ordinate represents a PL intensity in a linear scale. The PL intensity is represented by a normalized intensity normalized by the maximum intensity. When arsenic is not doped, the PL intensity is about 0.5. When arsenic is doped, the PL intensity can increase to 1. It has been found further that the PL intensity takes a maximum value in an arsenic concentration range from about 1×10¹⁸ (1E18) atoms/cm³ to about 1×10¹⁹ (1E19) atoms/cm³, independently from the V/III ratio. It indicates that the PL intensity can be increased about two times by arsenic doping. The emission wavelength did not show any change by arsenic doping. It is considered that a substantial compositional change does not occur.

This graph suggests the possibility that the emission intensity can be increased by doping As in the active layer of AlGaInP mixed crystal in a range from 1×10¹⁸ atoms/cm³ to 1×10¹⁹ atoms/cm³.

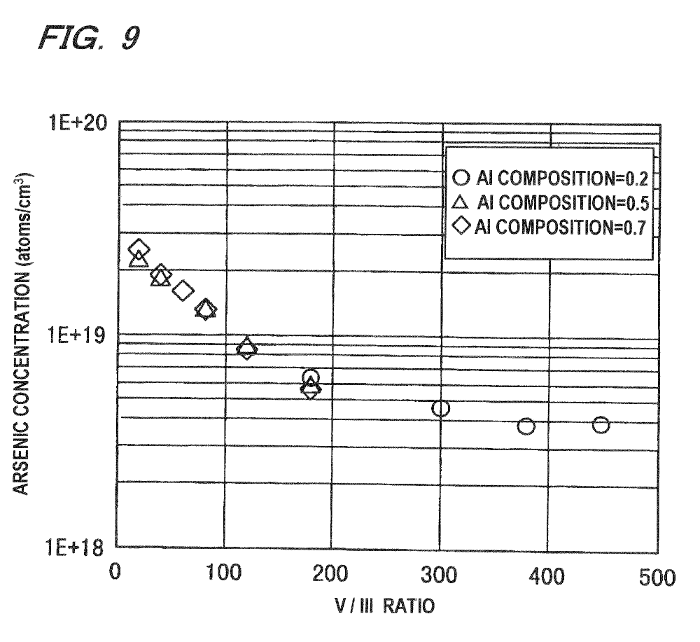

FIG. 9 is a graph illustrating the relation between arsenic concentration in (Al_{z}Ga_{1-z})_{0.5}In_{0.5}P layers and V/III ratio, when Al composition z is changed as 0.2, 0.5 and 0.7. The abscissa represents V/III ratio, and the ordinate represents As concentration in the unit of atoms/cm³. The As/III ratio was set constant at 0.01. Measured plots for the samples having different Al compositions are on one curve. It can be understood that arsenic is doped at approximately the same concentration independently from the Al composition. This graph indicates that the relation between the arsenic concentration and V/III ratio will not be changed even when the Al composition z in (Al_{z}Ga_{1-z})_{0.5}In_{0.5}P layer is changed.

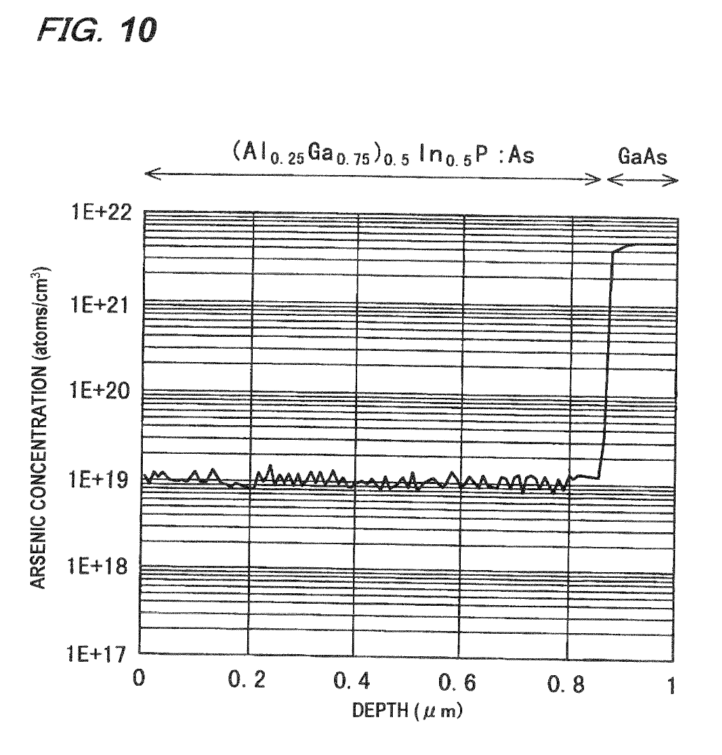

FIG. 10 is a graph indicating an arsenic concentration distribution in the (Al_{0.25}Ga_{0.75})_{0.5}In_{0.5}P:As layer epitaxially grown on an Si doped n-type GaAs substrate 21 and doped with arsenic at a concentration of about 1×10¹⁹ (1E19) atoms/cm³. The abscissa represents a depth from the sample surface in the unit of μm, and the ordinate represents an arsenic concentration in the unit of atoms/cm³. It can be understood that the (Al_{0.25}Ga_{0.75})_{0.5}In_{0.5}P layer at a constant arsenic concentration of about 1×10¹⁹ atoms/cm³ is grown on the GaAs substrate. It can be said that an arsenic concentration including a measuring error is in a range from 7×10¹⁸ atoms/cm³ to 1.4×10¹⁹ atoms/cm³(±35%) at most, and approximately in a range from 8×10¹⁸ atoms/cm³ to 1.3×10¹⁹ atoms/cm³(±25%). Diffusion of As from the GaAs substrate is not recognized.

It has been found from these experimental results that the effect of suppressing carbon capturing can be obtained by doping As at an impurity level and that the PL intensity can be improved by doping As at a proper concentration. Samples of light emitting diodes were manufactured by doping As in at least one of the active layer and the clad layers sandwiching the active layer. Phenomena caused by As doping were observed.

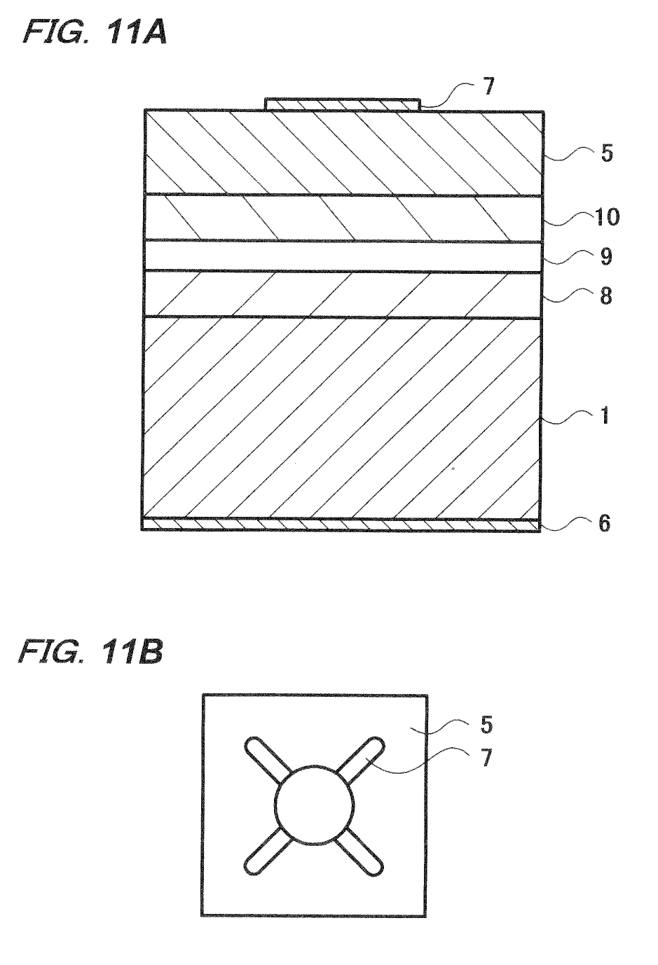

FIG. 11A is a schematic cross sectional view illustrating the fundamental structure of samples and comparative examples. Sequentially grown by MOCVD on the surface of an Si-doped n-type GaAs substrate 1 are an Si doped n-type (Al_{0.7}Ga_{0.3})_{0.5}In_{0.5}P clad layer 8 having a thickness of 1 μm, an (Al_{0.2}Ga_{0.8})_{0.5}In_{0.5}P active layer 9 having a thickness of 0.2 μm and not doped with conductivity affording impurities, a Zn doped p-type (Al_{0.7}Ga_{0.3})_{0.5}In_{0.5}P clad layer 10 having a thickness of 1 μm, and a Zn doped p-type current diffusion layer 5 having a thickness of 10 μm. A carrier concentration of the Si doped n-type clad layer 8 was set to 5×10¹⁷ (5E17) atoms/cm³, and a carrier concentration of the Zn doped p-type clad layer 10 was set to 5×10¹⁷ (5E17) atoms/cm³.

An n-side electrode 6 was formed on the bottom surface of the n-type GaAs substrate 1, and a p-side electrode 7 was formed on the p-type current diffusion layer 5 The n-side electrode 6 was made of Au—Ge—Ni, and the p-side electrode 7 was made of Au—Zn. After the electrodes were formed, the wafer was diced into plan shape of 250 μm×250 μm and packaged.

FIG. 11B is a plan view illustrating a pattern of the p-side electrode 7 on an external emission side. A cross-shaped electrode pattern was used The n-side electrode 6 is an electrode covering the whole bottom surface of the substrate.

According to the above-described experiment results, when As is doped at an impurity level, carbon capturing in a grown layer can be suppressed. When As is doped, the carbon capturing can be suppressed so that a low V/III ratio can be adopted. By doping arsenic into the active layer, the emission intensity of an active (light emitting) layer was increased.

In the light emitting diode samples, the target layer for As doping is at least one of the n-type clad layer, the active layer and the p-type clad layer. In doping As into the clad layer, the V/III ratio was set as low as possible, at 40, in order to obtain good morphology. The V/III ratio was set to 100 when the clad layer not doped with arsenic was grown. In doping As in the active layer, the V/III ratio was set to 450.

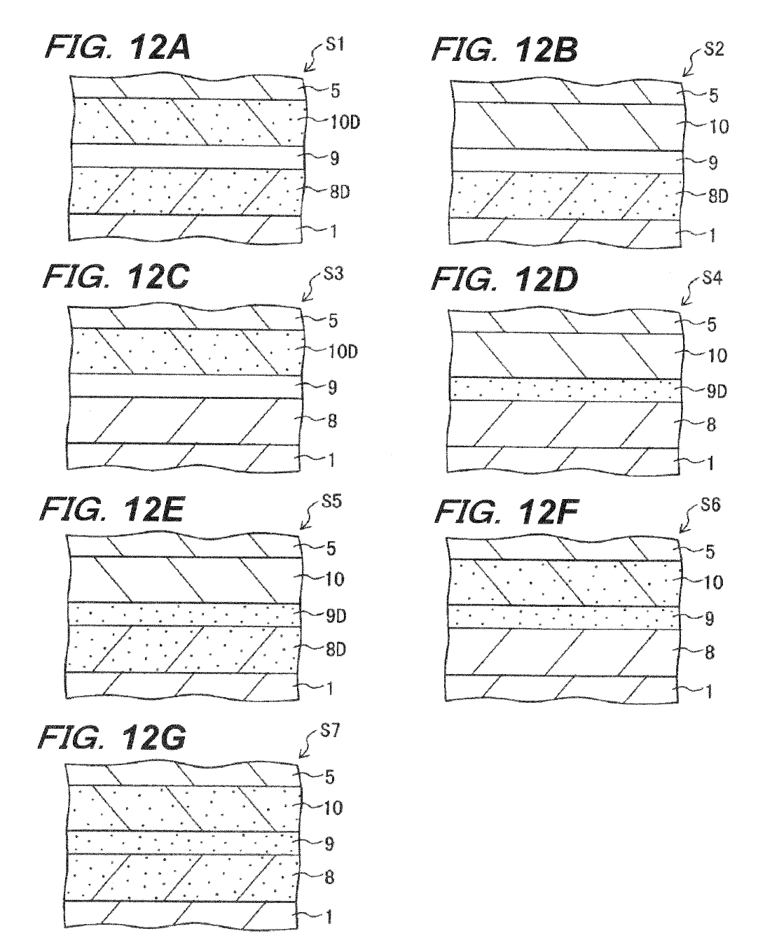

FIGS. 12A to 12G are schematic cross sectional views illustrating samples of seven types formed by doping As in at least one of the active layer and the two clad layers. For the lower n-type clad layer 8, non-doped active layer 9 and upper n-side clad layer 10, suffix “D” was added to the reference numeral when As is doped, i.e. 8D, 9D, and 10D.

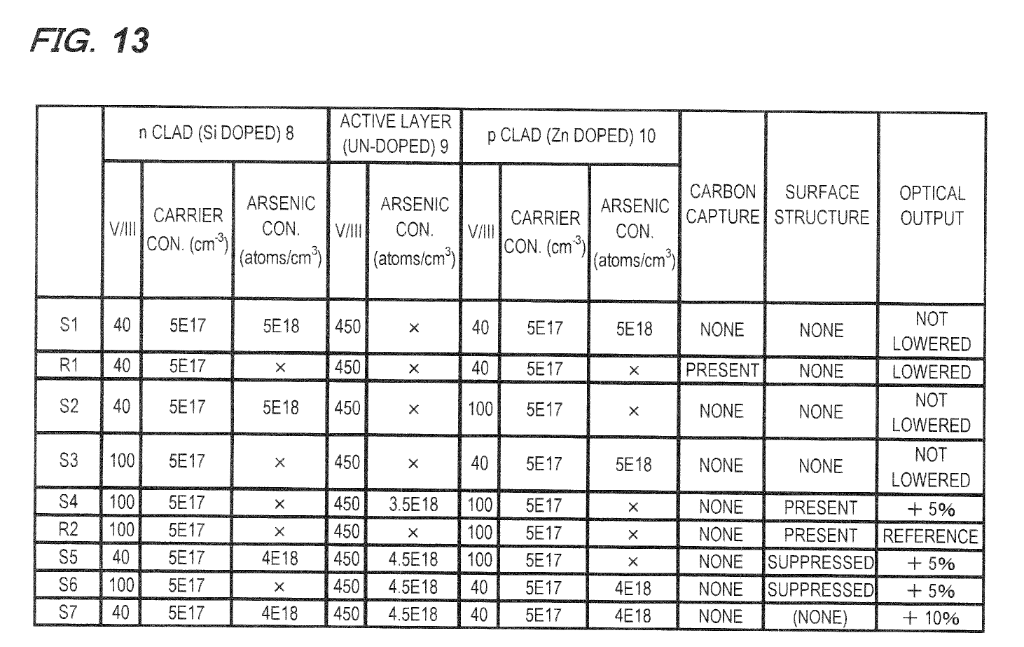

FIG. 13 is a table illustrating the summary of features of two comparative examples and seven samples.

Each light emitting diode was driven to emit light, to monitor an emission state, and measure an optical output Carbon concentration was measured by SIMS. In a light emitting diode having a GaP current diffusion layer which has a lattice mismatch with the GaAs substrate, uneven portions were formed on the current diffusion layer. Morphology evaluation was made on the p-type clad layer 10 exposed by etching and removing the current diffusion layer. There were found irregularity of the etching, and it was judged that strict quantitative evaluation is difficult. In order to make strict evaluation of morphology, it would be necessary to form a single epitaxial layer such as shown in FIG. 1. Even when strict evaluation of morphology was difficult, evaluation was possible by the presence/absence and the size of structure body. Therefore, evaluation of morphology was performed indirectly using structure body.

FIGS. 12A, 12B and 12C are partial cross sectional views illustrating the structures of samples S1, S2 and S3 whose clad layer or layers were doped with As. In the sample S1 shown in FIG. 12A, As was doped into both the clad layers, n-type clad layer 8D and p-type clad layer 10D, at 5×10¹⁸ (5E18) cm⁻³. V/III ratio during growth of both the clad layers 8D and 10D was set to 40 in order to maintain morphology in a good state. V/III ratio during growth of the active layer 9 was set at 450.

A comparative example R1 not doped with As was formed. The n-type clad layer 8 and the p-type clad layer 10 shown in FIG. 11 were grown at a V/III ratio of 40 without doping As. Surface morphology of the comparative example had no problem. This may be ascribed to setting the V/III ratio at 40. As the results of SIMS analysis, irregular residual carbon was recognized in the clad layers 8 and 10, and an optical output was reduced greatly in the area of residual carbon. A plurality of confirming experiments showed that carbon capturing areas in both the clad layers were not uniform, and the concentrations were neither constant. Since the V/III ratio was set to 40, it can be considered that carbon capturing is inevitable, and once the carbon capturing occurs, an optical output lowers greatly.

In the sample S2 shown in FIG. 12B, arsenic was doped in the n-type clad layer 8D at 5×10¹⁸ (5E18) cm⁻³, and V/III ratio during growth was set to 40. Arsenic was not doped in the p-type clad layer 10, and V/III ratio during growth was set to 100. Other points are similar to those of the sample S1. In the sample S3 shown in FIG. 12C, arsenic was doped in the p-type clad layer 10D at 5×10¹⁸ (5E18) cm⁻³, and V/III ratio during growth was set to 40. Arsenic was not doped in the n-type clad layer 8, and V/III ratio during growth was set to 100. Other points are similar to those of the sample S1. SIMS analysis did not detect carbon capturing, and an optical output reduction was neither observed.

FIG. 12D is a partial cross sectional view illustrating the structure of a sample S4 whose active layer was doped with As. Arsenic was doped in an active layer 9D at 3.5×10¹⁸ (3.5E18) cm⁻³, and V/III ratio during growth was set to 450. Arsenic was not doped in both the clad layers 8 and 10, and V/III ratio during growth was set to 100. Other points are similar to those of the sample S1.

A comparative example R2 was formed without doping As in the active layer. In the structure shown in FIG. 11, the n-type clad layer 8 was grown at V/III ratio of 100 without doping As, the active layer 9 was grown at V/III ration of 450 without doping As, and the p-type clad layer 10 was grown at V/III ratio of 100 without doping As. Other points are similar to those of the sample 4.

In the comparative example R2, uniform emission was obtained. Carbon capturing was not detected. This may be ascribed to the effects of setting the V/III ratio during growth of the clad layers to 100. However, formation of surface structures was recognized.

In the sample S4, it was recognized that an optical output increased about 5% of that of the comparative example. However, formation of surface structures was recognized similar to the comparative example R2. The effects of increasing an emission efficiency can be obtained by doping As in the active layer.

FIGS. 12E, 12F and 12G are partial cross sectional views illustrating the structures of samples S5, S6 and S7 whose active layer and at least one of the clad layers was doped with As. In the sample S5 shown in FIG. 12E, arsenic was doped in the n-type clad layer 8D and active layer 9D. Arsenic was doped in the n-type clad layer 8D at 4×10¹⁸ (4E18) cm⁻³, and V/III ratio during growth was set to 40. Arsenic was doped in the active layer 9D at 4.5×10¹⁸ (4.5E18) cm⁻³, and V/III ratio during growth was set to 450. Other points are similar to those of the sample S4. As compared to the sample S4, formation of surface structures was reduced in the sample S5. It was recognized that an optical output increased about 5% of that of the comparative example R2.

In the sample S6 shown in FIG. 12F, arsenic was doped in the active layer 9D and p-type clad layer 10D. Arsenic was doped in the active layer 9D at 4.5×10¹⁸ (4.5E18) cm⁻³, and V/III ratio during growth was set to 450. Other points are similar to those of the sample S4. As compared to the sample S4, formation of surface structures was reduced in the sample S6. It was recognized that an optical output increased about 5% of that of the comparative example R2. In the sample S7 shown in FIG. 12G, arsenic was doped in the active layer 9D and both clad layers 8D and 10D. Arsenic was doped in the n-type clad layer 8D at 4×10¹⁸ (4E18) cm⁻³, and V/III ratio during growth was set to 40. Arsenic was doped in the active layer 9D at 4.5×10¹⁸ (4.5E18) cm⁻³, and V/III ratio during growth was set to 450. Arsenic was doped in the p-type clad layer 10D at 4×10¹⁸ (4E18) cm⁻³, and V/III ratio during growth was set to 40. Other points are similar to those of the sample S4. As compared to the sample S4, formation of surface structures was hardly recognized in the sample S7. It was recognized that an optical output increased about 10% of that of the comparative example R2.

Table in FIG. 13 shows the summary of features of the samples S1 to S7 and comparative examples R1 and R2. In the samples S1 to S3 whose clad layers were doped with As, carbon capturing and an optical output reduction were suppressed In the samples S4 to S7 whose active layers were doped with As, carbon capturing was suppressed and an increase in optical output was recognized. Although arsenic is doped in the active layer, a change in emission wavelength was not observed. When arsenic is not dope in the active layer, variation in emission wavelength was in a range of about ±1 to 2 nm, and when arsenic is doped in the active layer, variation in emission wavelength was also in a range of about ±1 to 2 nm.

The structures of the seven samples illustrated in FIGS. 12A to FIG. 12G constitute embodiments. Various modifications of these embodiments are possible.

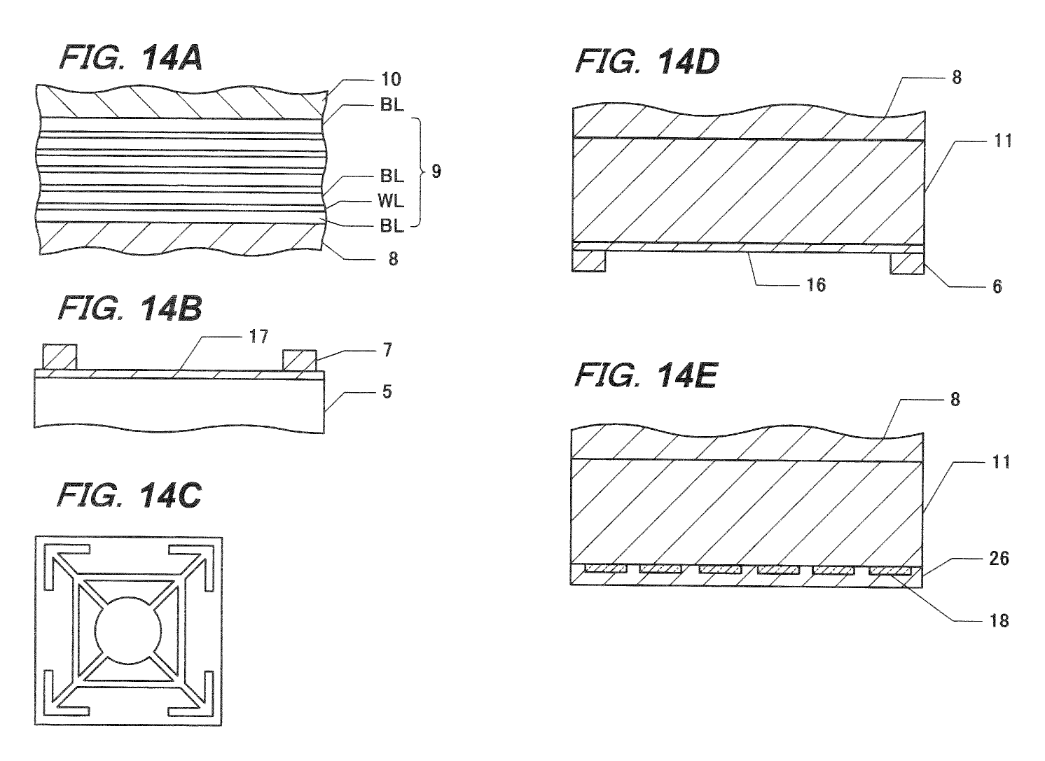

FIG. 14A is a partial cross sectional view illustrating a modification in which the active layer 9 has a multiple quantum well structure. The basic quantum well structure is formed by sandwiching a well layer WL with barrier layers BL. The well layer WL and barrier layer BL are repetitively stacked to form a multiple quantum well structure having a desired number of well layers. In the structure shown, six barrier layers BL sandwich five well layers. For example, the well layer is made of (Al_{0.2}Ga_{0.8})_{0.5}In_{0.5}P, and the barrier layer is made of (Al_{0.5}Ga_{0.5})_{0.5}In_{0.5}P. In place of multiple quantum well structure, single quantum well structure may be used. Barrier layers on both outermost sides may be omitted.

FIG. 14B illustrates a modification of a p-side electrode structure. A transparent electrode 17 of ITO, ZnO or the like is formed on the whole surface of a p-type current diffusion layer 5, and a p-side electrode 7 is formed locally, e.g., along a circumferential edge, on the transparent electrode 17. Carriers can be supplied to the whole surface of the current diffusion layer through the transparent electrode, while limiting the area of the light shielding p-side electrode 7.

FIG. 14C illustrates another modification of a p-side electrode. Fine electrodes each having a narrow width are disposed at two positions in the radial direction, and are connected by diagonally oriented cross-shaped electrode. A circular contact is formed at a central area. There are various other fine electrode patterns.

FIG. 14D illustrates the structure of a transparent substrate 11 made of Si doped n-type AlGaAs. A transparent electrode 16 is formed on the whole bottom surface of the substrate, and an n-side electrode 6 is locally formed on the transparent electrode 16. An optical output can be obtained also from the bottom side.

FIG. 14E illustrates another modification of a substrate side electrode formed on the bottom surface a transparent substrate. Transparent insulating film patterns 18 made of SiO₂ etc. are disposed dispersively, e.g., in a matrix shape, on the bottom surface of a substrate 11 which is transparent to the emission wavelength, to selectively expose the bottom surface of the substrate 11, e.g., in a lattice shape. An n-side electrode 26 is formed on the substrate 11, covering the transparent insulating film patterns 18. The n-side electrode 26 forms an ohmic contact in areas contacting the substrate 11. Although the ohmic contact is hard to provide a high reflectivity, lamination of the transparent insulating film 18 and the n-side electrode 26 provides a high reflectivity. Reflected light is obtained from the front surface side. Although description was made on the case where the reflection enhancing structure utilizing the transparent insulating film patterns is formed on the bottom surface of the substrate, the reflection enhancing structure may be formed in other areas.

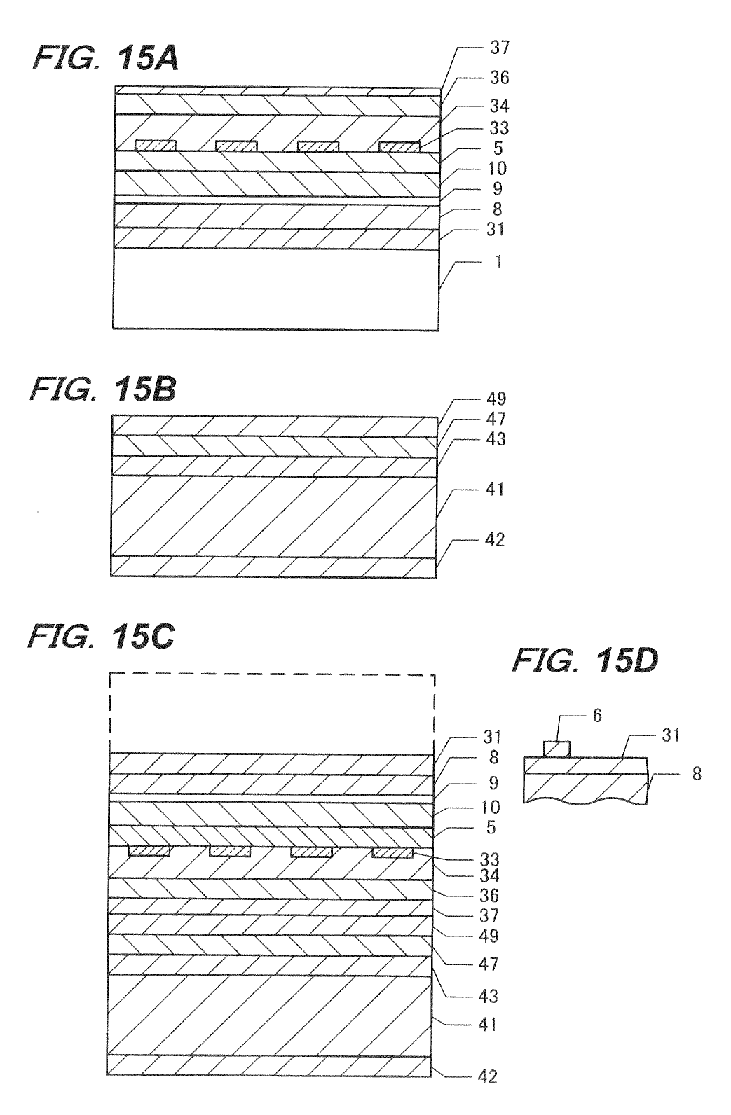

FIGS. 15A to 15D are cross sectional views illustrating a semiconductor light emitting device according to another modification.

As illustrated in FIG. 15A, an n-type AlInGaP buffer layer 31 is grown by MOCVD on a GaAs substrate 1. Similar to the embodiment illustrated in FIG. 11A, grown on the n-type AlInGaP buffer layer 31 are an n-type AlInGaP clad layer 8, an AlInGaP active layer 9, a p-type AlInGaP clad layer 10 and a p-type AlInGaP current diffusion layer 5. At least one of the active layer and the clad layers is doped with As.

A transparent insulating film 33 made of, e.g., silicon oxide, is deposited on the p-type current diffusion layer 5 by CVD, and patterned by etchant such as dilute hydrofluoric acid, by using a photoresist pattern as an etching mask. Silicon oxide patterns 33 disposed, for example, in a matrix shape at a constant pitch, are left. A p-side ohmic electrode 34 of, e.g. Au—Zn, is formed on the p-type current diffusion layer 5 by sputtering or the like, covering the silicon oxide patterns 33. A barrier layer 36 such as a TaN/TiW/TaN lamination and a bond assisting layer 37 such as an Ni/Au lamination are formed on and above the p-type ohmic electrode 34. The reflection enhancing structure formed by the transparent insulating film and the ohmic electrode is embedded in the lamination structure. The GaAs substrate 1 may be a non-dope substrate because it will be removed later.

As illustrated in FIG. 15B, Pt ohmic electrodes 42 and 43 are formed on both sides of a conductive Si substrate 41, and a Ti bonding layer 46, an Ni/Au bond assisting layer 47 and an AuSn eutectic metal layer 49 are formed on and above the upper ohmic electrode 43. The Si substrate 41 is used as a support substrate of the device.

As illustrated in FIG. 15C, the GaAs substrate 1 formed with the light emitting diode is disposed up side down above the Si support substrate 41, and the bond assisting layer 37 is abutted on the eutectic metal layer 49 to thermally bond together. The eutectic metal layer 49 and bond assisting layers 37 and 47 constitute a bonding layer. Thereafter, the GaAs substrate 1 is etched and removed.

As illustrated in FIG. 15D, an n-side ohmic electrode 6 of Au—Ge—Ni or the like is formed locally on the exposed n-type AlInGaP buffer layer 31. In this modification, the reflection enhancing structure using the transparent insulating layer 33 is disposed dispersively above the substrate 41, the p-type current diffusion layer 5 is disposed on the reflection enhancing structure and the p-side ohmic electrode 34, and the p-type clad layer 10, the active layer 9 and the n-type clad layer 8 are disposed thereon. The n-type clad layer 8 is disposed above the p-type clad layer 10.

Although the active layer is made of AlGaInP and the clad layer is made of AlInP or AlGaInP, these layers may be made of other materials. The current diffusion layer may be made of material other than GaP. In this case, a band gap of the clad layer is set wider than that of the active layer, and a band gap of the current diffusion layer is also set wider than that of the active layer. Since an organic metal source is also used when epitaxial growth is performed by metal organic molecular beam epitaxy (MO-MBE), there is a possibility that carbon enters the growth layer. If arsenic is doped at the same time, it is expected that the carbon capturing can be suppressed. MOCVD and MO-MBE are collectively called organic metal vapor growth.

The present invention has been described in connection with the embodiments. The present invention is not limited to the embodiments. For example, it is apparent that those skilled in the art can make various modifications, improvements, combinations and the like.

What we claim are:

1. A semiconductor light emitting device comprising:
a substrate;
a first clad layer formed above said substrate and made of AlGaInP mixed crystal of a first conductivity type;
an active layer formed on said first clad layer and made of AlGaInP mixed crystal; and
a second clad layer formed on said active layer and made of AlGaInP mixed crystal of a second conductivity type opposite to said first conductivity type,
wherein said first clad layer and said second clad layer have a band gap wider than a band gap of said active layer, and at least one of said active layer and said first and second clad layers is doped with arsenic at an impurity concentration level not changing the band gap.

2. The semiconductor light emitting device according to claim 1, wherein concentration of said arsenic is 2×10²⁰ atoms/cm³ or lower.

3. The semiconductor light emitting device according to claim 1, wherein concentration of said arsenic is 1×10²⁰ atoms/cm³ or lower, and arsenic concentration distribution is uniform within ±35% along a layer thickness direction.

4. The semiconductor light emitting device according to claim 1, wherein at least one of said first and second clad layers has arsenic concentration in a range from 4×10¹⁸ atoms/cm³ to 1×10¹⁹ atoms/cm³.

5. The semiconductor light emitting device according to claim 1, wherein said active layer has arsenic concentration in a range from 1×10¹⁸ atoms/cm³ to 1×10¹⁹ atoms/cm³.

6. The semiconductor light emitting device according to claim 1, wherein arsenic is doped in said active layer and at least one of said first and second clad layers.

7. The semiconductor light emitting device according to claim 6, wherein said active layer has arsenic concentration in a range from 1×10¹⁸ atoms/cm³ to 1×10¹⁹ atoms/cm³, and said at least one of said first and second clad layers has arsenic concentration in a range from 4×10¹⁸ atoms/cm³ to 1×10¹⁹ atoms/cm³, and the arsenic concentration of said active layer is higher than the arsenic concentration of said at least one clad layer.

8. The semiconductor light emitting device according to claim 1, wherein said substrate is made of semiconductor material of said first conductivity type transparent to an emission wavelength of said active layer.

9. The semiconductor light emitting device according to claim 8, further comprising:
a transparent insulating pattern formed on a bottom surface of said substrate and selectively exposing the bottom surface of said substrate; and
a first ohmic electrode forming an ohmic contact in a contact area of the bottom surface of said substrate and covering said transparent insulating pattern.

10. The semiconductor light emitting device according to claim 1, wherein said substrate is a silicon substrate, the semiconductor light emitting device further comprising:
second ohmic electrodes formed on both surfaces of said silicon substrate;
eutectic metal layer formed above one of said second ohmic electrodes;
third ohmic electrode disposed above said eutectic metal layer;
lamination of said first clad layer, said active layer, and said second clad layer disposed on said third ohmic electrode; and
fourth ohmic electrode formed above said second clad layer.

11. The semiconductor light emitting device according to claim 10, further comprising:
transparent insulating film patterns disposed between said third ohmic electrode and said first clad layer.

12. The semiconductor light emitting device according to claim 1, further comprising:
a current diffusion layer of GaP of said second conductivity type formed on said second clad layer; and
a surface side electrode formed on said current diffusion layer.

13. The semiconductor light emitting device according to claim 1, wherein said active layer has a quantum well structure.

14. A method for manufacturing a semiconductor light emitting device including steps of:
transporting a semiconductor substrate into an organic metal vapor growth system; and
epitaxially growing a first clad layer of AlGaInP mixed crystal of a first conductivity type, an active layer of AlGaInP mixed crystal, and a second clad layer of AlGaInP mixed crystal of a second conductivity type opposite to the first conductivity type, sequentially by organic metal vapor growth above the semiconductor substrate, while doping in situ, at least one of three layers of the first and second clad layers and the active layer, with arsenic at an impurity concentration level not changing a band gap.

15. The method for manufacturing a semiconductor light emitting device according to claim 14, wherein a concentration of said in-situ doped arsenic is 2×10²⁰ atoms/cm³ or lower.

16. The method for manufacturing a semiconductor light emitting device according to claim 14, wherein concentration of said in-situ doped arsenic is 1×10²⁰ atoms/cm³ or lower, and arsenic concentration distribution is uniform within ±35% along a layer thickness direction.

17. The method for manufacturing a semiconductor light emitting device according to claim 14, wherein at least one of said first and second clad layers is epitaxially grown, while doping arsenic in situ in arsenic concentration range from 4×10¹⁸ atoms/cm³ to 1×10¹⁹ atoms/cm³, and controlling V/III ratio in a range from 20 to 60.

18. The method for manufacturing a semiconductor light emitting device according to claim 14, wherein said active layer is epitaxially grown while doping arsenic in situ in arsenic concentration range from 1×10¹⁸ atoms/cm³ to 1×10¹⁹ atoms/cm³.

19. The method for manufacturing a semiconductor light emitting device according to claim 14, wherein said active layer and at least one of said first and second clad layers are epitaxially grown while doping arsenic in situ.

20. The method for manufacturing a semiconductor light emitting device according to claim 14, wherein said active layer is epitaxially grown while doping arsenic in situ in arsenic concentration range from 1×10¹⁸ atoms/cm³ to 1×10¹⁹ atoms/cm³, said at least one of said first and second clad layers is epitaxially grown while doping arsenic in situ in arsenic concentration range from 4×10¹⁸ atoms/cm³ to 1×10¹⁹ atoms/cm³, and the arsenic concentration of said active layer is set higher than the arsenic concentration of said at least one clad layer.
